(19) United States
(12) Patent Application Publication
(10) Pub. No.: US 2017/0262378 A1
(43) Pub. Date: Sep. 14, 2017

(54) SYSTEM AND METHOD FOR RAM CAPACITY OPTIMIZATION USING ROM-BASED PAGING

(71) Applicant: QUALCOMM INCORPORATED, SAN DIEGO, CA (US)

(72) Inventors: NIEYAN GENG, SAN DIEGO, CA (US); ANDRES OPORTUS VALENZUELA, SAN DIEGO, CA (US); GURVINDER SINGH CHHABRA, SAN DIEGO, CA (US)

(21) Appl. No.: 15/068,109

(22) Filed: Mar. 11, 2016

(51) Int. Cl. G06F 12/1009; G06F 12/06; G11C 7/10; G06F 12/128

(52) U.S. Cl. CPC G06F 12/1009; G06F 12/128; G06F 12/0638; G11C 7/1072; G06F 2212/205; G06F 2212/69

(57) ABSTRACT

Various embodiments of methods and systems for memory paging in a system on a chip (“SoC”) are disclosed. An exemplary method includes identifying a subset of a baseline data image stored in a secondary storage device and determining that a revision data image requires an update of the subset. In response to the update, generating a diff file that represents binary differences between the revision data image subset and the baseline data image subset. Next, storing the diff file in a primary storage device and, upon receiving a request for a data block associated with the revision data image that causes a page fault, generating the requested data block based on a combination of the baseline data image and the diff file.

### DESCRIPTION OF THE RELATED ART

Portable computing devices (“PCDs”) are becoming necessities for people on personal and professional levels. These devices may include cellular telephones, portable digital assistants (“PDAs”), portable game consoles, palmtop computers, and other portable electronic devices.

One aspect of PCDs that is in common with most computing devices is the use of electronic memory components for storing instructions and/or data. Various types of memory components may exist in a PCD, each designated for different purposes and each with its own set of advantages and disadvantages. Volatile rapid access memory (“RAM”), for example, is in high demand by PCD designers to be used as a primary memory component because it is extremely fast in responding to data requests from processing components. But, RAM is expensive and sometimes impractical to scale due to limited size options. By contrast, read only memory (“ROM”) is inexpensive, but is relatively slower in its response time and less practical for managing data updates due to the original data image being permanently “burned” into the unchangeable, non-volatile ROM at the time of manufacture.

Often, a baseline data image is stored in ROM and subsequent updates or revisions to the data image are managed in RAM. As one of ordinary skill in the art understands, managing in RAM software updates to data instantiated in ROM can take up a lot of valuable RAM capacity that could be used for other purposes. Therefore, there is a need in the art for a system and method that optimizes RAM space utilization for software updates. More specifically, there is a need in the art for a system and method that optimizes RAM capacity through the use of ROM-based paging.

### SUMMARY OF THE DISCLOSURE

Various embodiments of methods and systems for memory paging in a system on a chip (“SoC”) are disclosed. An exemplary method includes identifying a subset of a baseline data image stored in a secondary storage device, such as a read only memory (“ROM”) device, and determining that a revision data image requires an update of the subset. In response to the update, generating a diff file that represents binary differences between the revision data image subset and the baseline data image subset. Next, storing the diff file in a primary storage device, such as a double data rate (“DDR”) dynamic random access memory device. Subsequently, upon receiving a request for a data block associated with the revision data image that causes a page fault, generating the requested data block based on a combination of the baseline data image and the diff file. Placing the generated requested data block in either a swap pool area designated in the primary storage device or in a cache closely coupled to a processing component that initiated the request. Finally, responding to the request by providing the generated requested data block to the processing component.

### BRIEF DESCRIPTION OF THE DRAWINGS

In the drawings, like reference numerals refer to like parts throughout the various views unless otherwise indicated. For reference numerals with letter character designations such as “102A” or “102B”, the letter character designations may differentiate two like parts or elements present in the same figure. Letter character designations for reference numerals may be omitted when it is intended that a reference numeral to encompass all parts having the same reference numeral in all figures.

FIG. 1 is a functional block diagram illustrating an exemplary, non-limiting aspect of a portable computing device (“PCD”) in the form of a wireless telephone for implementing RAM capacity optimization using ROM-based paging methods and systems;

FIG. 2 is a functional block diagram illustrating an embodiment of an on-chip system for executing ROM-based paging methods and systems;

FIG. 3 illustrates generation of a device image at build time according to embodiments of the solution for ROM-based paging;

FIG. 4 illustrates a runtime execution according to embodiments of the solution for ROM-based paging using a swap pool in RAM;

FIG. 5 illustrates a runtime execution according to embodiments of the solution for ROM-based paging using a cache;

FIG. 6 is a logical flowchart of a method for ROM-based paging according to embodiments of the solution using a swap pool in RAM; and

FIG. 7 is a logical flowchart of a method for ROM-based paging according to embodiments of the solution using a cache.

### DETAILED DESCRIPTION

The word “exemplary” is used herein to mean serving as an example, instance, or illustration. Any aspect described herein as “exemplary” is not necessarily to be construed as exclusive, preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

In this description, reference to double data rate (“DDR”) memory components and/or dynamic random access memory (“DRAM”) and/or “primary” memory components will be understood to envision any of a broader class of volatile random access memory (“RAM”) used for data storage and will not limit the scope of the solutions disclosed herein to a specific type or generation of RAM.

In this description, reference to “external memory device” and/or “ROM” and/or “secondary” memory and the like refers to a broader class of non-volatile (i.e., retains its data after power is removed), one-time programmable and nonreversible memory for storing executable code and/or data and will not limit the scope of the solutions disclosed. As such, it will be understood that use of the terms envisions any programmable read-only memory or field programmable non-volatile memory suitable for a given application of a solution such as, but not limited to, embedded multimedia card (“eMMC”) memory, electrically erasable programmable read-only memory (“EEPROM”), flash memory, etc.

In this description, the term “page fault” generally refers to an event where a processing component executing a program requests a data page not presently stored in primary storage. The invalid memory reference may cause the memory controller and/or page fault handler to determine the location of the requested page data in secondary storage, identify an unused memory space in the primary storage, retrieve the requested page from secondary storage and save a copy into the identified space in the primary storage, update a page table associated with the primary storage, and return instructions to the processing component to make a new request for the page data at the new location of the copy.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “central processing unit (“CPU”),” “digital signal processor (“DSP”),” “graphical processing unit (“GPU”),” and “chip” are used interchangeably. Moreover, a CPU, DSP, GPU or a chip may be comprised of one or more distinct processing components generally referred to herein as “core(s).”

In this description, the term “portable computing device” (“PCD”) is used to describe any device operating on a limited capacity power supply, such as a battery. Although battery operated PCDs have been in use for decades, technological advances in rechargeable batteries coupled with the advent of third generation (“3G”) and fourth generation (“4G”) wireless technology have enabled numerous PCDs with multiple capabilities. Therefore, a PCD may be a cellular telephone, a satellite telephone, a pager, a PDA, a smartphone, a navigation device, an “ebook” or reader, a media player, a handheld game console, a combination of the aforementioned devices, a laptop computer with a wireless connection, among others.

ROM-based paging systems and methods according to the solution work to manage capacity in a primary storage component, such as a double data rate (“DDR”) memory device, by only storing new data from a software revision in the DDR. Unlike prior art solutions that store the entire image for a software update in the primary storage, embodiments of the present solution only store what “has changed” in a candidate portion of an original software instantiation, i.e. embodiments of the present solution store in the primary storage a “delta” or “diff” image of the data that has changed in a candidate portion of a baseline data image due to a software upgrade.

As such, because the entire candidate portion is not stored in the primary storage device (only the delta of data between the original candidate and the upgraded candidate), a page request on the candidate portion of the software from a processing component will generate a page fault, as would be understood by one of ordinary skill in the art. That is, a request for a page of data from the candidate portion that the processing component expects to be located in the primary storage results in a page fault when a memory manager module (comprising a memory controller) determines that the requested data is not presently stored in the primary storage. Embodiments of the solution respond by acquiring the requested page from a permanent instantiation in the secondary storage, such as a read only memory (“ROM”), and updating it with data from the delta file stored in the primary storage. The new updated file is then placed in a swap pool area of the primary storage so that the request from the processing component may be serviced from that swap pool location. In this way, embodiments of the solution optimize the use of valuable primary storage space by avoiding the need to store entire images of updated candidate portions of a software file—only the delta file, which is necessarily smaller than the entire updated candidate portion, is stored in the primary storage.

As one of ordinary skill in the art would acknowledge, primary storage such as DRAM is valuable to PCD designers as it is in high demand for providing various functionalities to a PCD user. Simply adding more DRAM is not always a viable choice for satisfying the demand, as DRAM can be cost prohibitive. As such, when an application grows in size due to software updates or other reasons, it may be desirable to leverage more cost effective storage solutions such as secondary storage devices in the form of ROM.

Thus, embodiments of the solution seek to leverage ROM as a way to address the issue of a growing image size for a given application. Again, prior art solutions simply accommodate a growing image size by storing the ever changing and additional data in RAM, but embodiments of the present solution avoid the need to allocate large amounts of RAM for such purposes. Embodiments of the solution use ROM that may already exist in a system or, it is envisioned, may leverage a relatively small piece of on-chip ROM added for the purpose of accommodating a growing image size. In this way, embodiments of the solution avoid the need to add ever larger sizes of expensive DRAM.

Advantageously, embodiments of the solution efficiently patch data stored in ROM without having to use a lookup table in RAM to determine whether the requested data is located in RAM or ROM. To accomplish this, embodiments work from an original, baseline instantiation in the ROM and, when an updated instantiation of the data is required, a difference (a binary difference) between the updated instantiation and the baseline instantiation is determined. The diff data, or “delta” file, that represents the binary difference as determined at build time (i.e., prior to runtime) is stored in the DRAM primary storage.

The requested data is paged from the ROM and it is determined whether the data has been updated from the previous version. If it has been updated, then the diff file is located in the DRAM and the requested page is generated as a patched page on demand from the diff file in combination with the baseline data stored in ROM. The patched page may be stored in a processor cache or swap pool location in DRAM and executed from that location.

Advantageously, the amount of DRAM needed for a given software update is relatively small because only enough DRAM to accommodate the binary difference between the baseline image and the updated image is required. By contrast, in prior art patching methods, patching occurs at the variable/function level so that even if a single byte of data has changed from the baseline instantiation, the whole function gets patched. Embodiments of the present solution may be operable to patch at the binary level, accommodating software updates at the page level or cache line level.

Certain embodiments of the solution may be viewed as an extension or improvement of traditional demand paging methodologies. As one of ordinary skill in the art of prior art demand paging would understand, when a page fault occurs in the DRAM, the requested page is acquired from a secondary storage location and copied into a selected location in DRAM. The selected location is then mapped into a lookup table in DRAM and the page is executed from the selected location. Embodiments of the solution accomplish the paging by acquiring the baseline version of the requested page from the secondary storage location and then updating the page based on diff data stored in the DRAM to create a patched page. The patched page is then stored in a swap pool location in DRAM, or in a cache of the requesting processing component, and the request is filled from that point. Once the patched page generated according to an embodiment of the solution is stored in the DRAM or cache, traditional demand paging algorithms may be leveraged to flush old pages, overwrite pages, etc.

The scope of the solution disclosed herein is not limited to using any one algorithm for generation of the diff/delta file. Even so, certain algorithms for determining the binary difference between a baseline image and an updated image may be novel in, and of, themselves. It is envisioned that certain embodiments of a ROM-based paging system and method according the proposed solution may utilize a diff or patch algorithm that represents the image diff data in the form of an edit script. Consistent with that which is described above and below, the edit script may be used with a baseline image to reconstruct a revision software image.

To improve the runtime image reconstruction performance, an edit script may be organized at the page boundary, i.e. on fixed size blocks or pages. Each requested page may be reconstructed independently using the edit information from the edit script that includes edit commands. The edit commands define a set of reconstruction operations that provide for combining the baseline image with the diff file data to generate a patched or updated page being requested by a processing component. Edit scripts may contain metadata and a list of pages that contain the various edit commands.

As illustrated below, it is envisioned that a diff algorithm leveraging edit scripts may use four types of edit commands: copy, small copy, insert and partial copy.

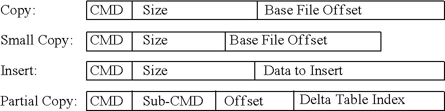

The “copy” and “small copy” commands may be used to copy a block of data from the baseline image located at a certain offset within the baseline image, with the “small copy” command using a relatively smaller amount of bits to encode the data block size. The “copy” and “small copy” commands may be applicable when the block of data in the baseline image and the associated block of data in the revised software image (i.e., the updated or modified image) are exactly the same or very similar in contents.

The “insert” command may be used to insert a block of data into the baseline image to generate the patched page. The data that needs to be inserted may be embedded in the edit script.

The “partial copy” command may be used on top of a copy or small copy command to “fix” a word in the previously copied data. A partial copy command may be used when the block of data is similar between the baseline image and the revision image and the block may be copied to fix some portion of it required due to address changes. The sub-CMD in a partial copy edit script may be used to identify the location of the small change coming from a global table or local cache, depending on embodiment. The address change may be used to implement changes in functions having numerous common offsets (a global table may be used to store the offsets and a most recently used offset table may be cached when a page is reconstructed according to an embodiment of the solution).

To generate the edit scripts, the particular part of the revision image of concern may be divided into pages. Subsequently, for each word in a page its symbol may be determined along with the same symbol in the baseline image. If there is no equivalent symbol in the baseline image, an insert command may be created to represent the data block for the new symbol. If there is an equivalent symbol in the baseline image, and the symbol length is the same as that which is in the revision image, a copy command may be created to copy the whole symbol with partial copy commands created on top by scanning through the page, word by word. If there is an equivalent symbol in the baseline image, but the length of the symbol is not the same as that which appears in the revision image, one word from the revision image may be selected from the page and used to find a longest matched block in the baseline symbol (may be exact match or fuzzy match). Subsequently, a copy command and multiple partial copy commands may be created for the match block.

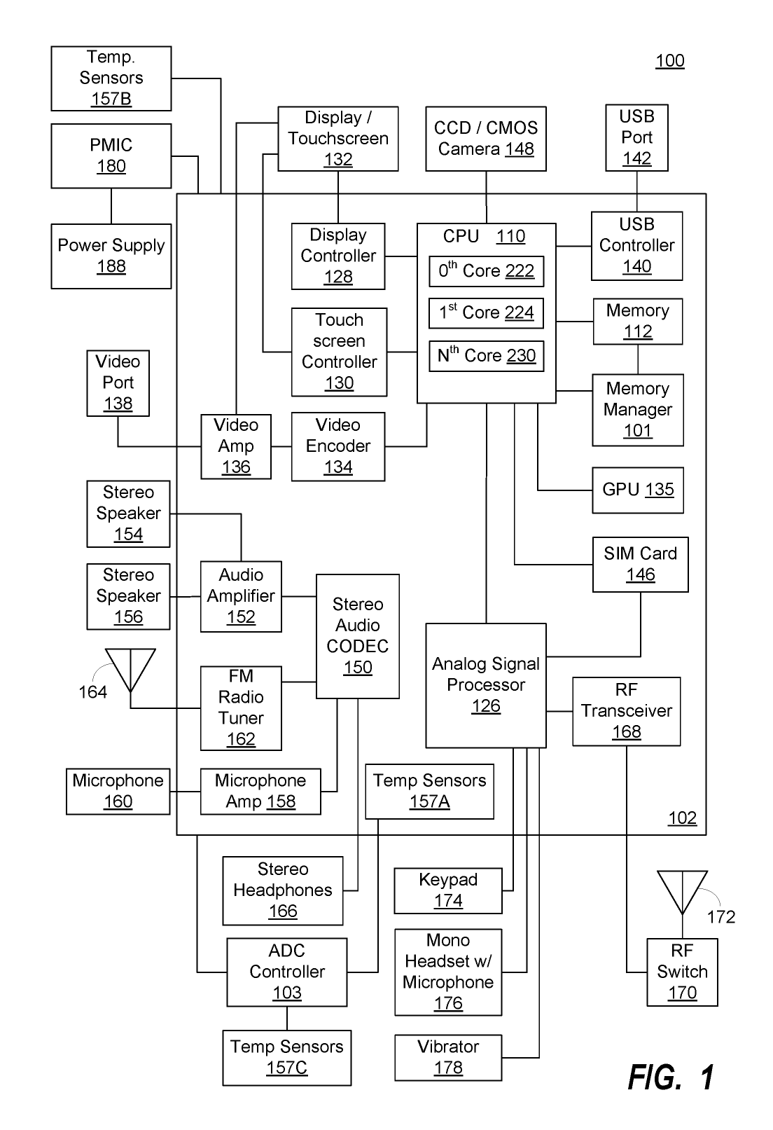

FIG. 1 is a functional block diagram illustrating an exemplary, non-limiting aspect of a portable computing device (“PCD”) 100 in the form of a wireless telephone for implementing RAM capacity optimization using ROM-based paging methods and systems. As shown, the PCD 100 includes an on-chip system 102 that includes a multi-core central processing unit (“CPU”) 110 and an analog signal processor 126 that are coupled together. The CPU 110 may comprise a zeroth core 222, a first core 224, and an Nth core 230 as understood by one of ordinary skill in the art. Further, instead of a CPU 110, a digital signal processor (“DSP”) may also be employed as understood by one of ordinary skill in the art.

In general, the memory manager 101 may be formed from hardware and/or software and may be responsible for generating diff files, servicing page faults and satisfying page requests according to embodiments of ROM-based paging solutions. Advantageously, embodiments of the solution may provide for optimized RAM utilization by only storing the diff data that represents a difference between a baseline image stored in ROM and a revised image associated with a software update. Using the diff data, a memory manager 101 may respond to a page fault by retrieving a baseline image data from ROM and modifying it based on diff data stored in RAM. The resulting modified image may be stored in RAM and used to satisfy the page request from that point.

As illustrated in FIG. 1, a display controller 128 and a touch screen controller 130 are coupled to the digital signal processor 110. A touch screen display 132 external to the on-chip system 102 is coupled to the display controller 128 and the touch screen controller 130. PCD 100 may further include a video encoder 134, e.g., a phase-alternating line (“PAL”) encoder, a sequential couleur avec memoire (“SECAM”) encoder, a national television system(s) committee (“NTSC”) encoder or any other type of video encoder 134. The video encoder 134 is coupled to the multi-core CPU 110. A video amplifier 136 is coupled to the video encoder 134 and the touch screen display 132. A video port 138 is coupled to the video amplifier 136. As depicted in FIG. 1, a universal serial bus (“USB”) controller 140 is coupled to the CPU 110. Also, a USB port 142 is coupled to the USB controller 140. A memory 112, which may include a PoP memory, a cache 114, a ROM 113, a one time programmable (“OTP”) memory, an external memory device such as a flash memory, a RAM memory such as a DDR device, etc., may also be coupled to the CPU 110 and memory manager 101.

A subscriber identity module (“SIM”) card 146 may also be coupled to the CPU 110. Further, as shown in FIG. 1, a digital camera 148 may be coupled to the CPU 110. In an exemplary aspect, the digital camera 148 is a charge-coupled device (“CCD”) camera or a complementary metal-oxide semiconductor (“CMOS”) camera.

As further illustrated in FIG. 1, a stereo audio CODEC 150 may be coupled to the analog signal processor 126. Moreover, an audio amplifier 152 may be coupled to the stereo audio CODEC 150. In an exemplary aspect, a first speaker 154 and a second speaker 156 are coupled to the audio amplifier 152. FIG. 1 shows that a microphone amplifier 158 may be also coupled to the stereo audio CODEC 150. Additionally, a microphone 160 may be coupled to the microphone amplifier 158. In a particular aspect, a frequency modulation (“FM”) radio tuner 162 may be coupled to the stereo audio CODEC 150. Also, an FM antenna 164 is coupled to the FM radio tuner 162. Further, stereo headphones 166 may be coupled to the stereo audio CODEC 150.

FIG. 1 further indicates that a radio frequency (“RF”) transceiver 168 may be coupled to the analog signal processor 126. An RF switch 170 may be coupled to the RF transceiver 168 and an RF antenna 172. As shown in FIG. 1, a keypad 174 may be coupled to the analog signal processor 126. Also, a mono headset with a microphone 176 may be coupled to the analog signal processor 126. Further, a vibrator device 178 may be coupled to the analog signal processor 126. FIG. 1 also shows that a power supply 188, for example a battery, is coupled to the on-chip system 102 through a power management integrated circuit (“PMIC”) 180. In a particular aspect, the power supply 188 includes a rechargeable DC battery or a DC power supply that is derived from an alternating current (“AC”) to DC transformer that is connected to an AC power source.

The CPU 110 may also be coupled to one or more internal, on-chip thermal sensors 157A as well as one or more external, off-chip thermal sensors 157B. The on-chip thermal sensors 157A may comprise one or more proportional to absolute temperature (“PTAT”) temperature sensors that are based on vertical PNP structure and are usually dedicated to complementary metal oxide semiconductor (“CMOS”) very large-scale integration (“VLSI”) circuits. The off-chip thermal sensors 157B may comprise one or more thermistors. The thermal sensors 157 may produce a voltage drop that is converted to digital signals with an analog-to-digital converter (“ADC”) controller 103. However, other types of thermal sensors 157 may be employed.

The touch screen display 132, the video port 138, the USB port 142, the camera 148, the first stereo speaker 154, the second stereo speaker 156, the microphone 160, the FM antenna 164, the stereo headphones 166, the RF switch 170, the RF antenna 172, the keypad 174, the mono headset 176, the vibrator 178, thermal sensors 157B, the PMIC 180 and the power supply 188 are external to the on-chip system 102. It will be understood, however, that one or more of these devices depicted as external to the on-chip system 102 in the exemplary embodiment of a PCD 100 in FIG. 1 may reside on chip 102 in other exemplary embodiments.

In a particular aspect, one or more of the method steps described herein may be implemented by executable instructions and parameters stored in the memory 112 or as form the memory manager 101 and/or its page fault handler. Further, the memory manager 101, the memory 112, the instructions stored therein, or a combination thereof may serve as a means for performing one or more of the method steps described herein.

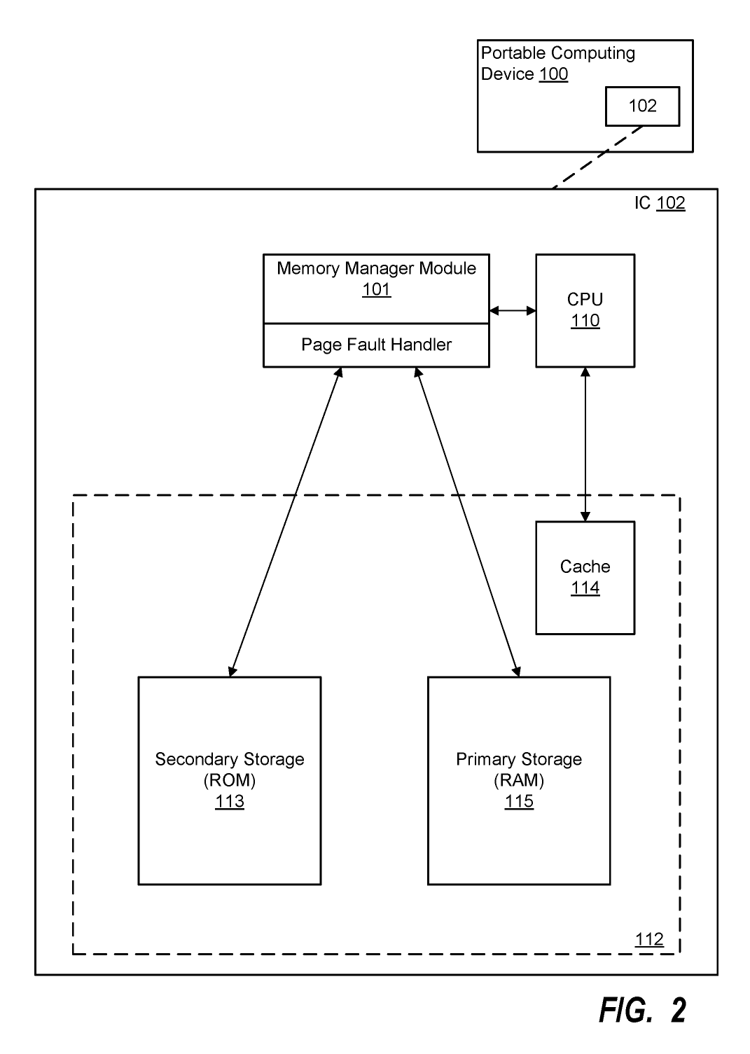

FIG. 2 is a functional block diagram illustrating an embodiment of an on-chip system 102 for executing ROM-based paging methods and systems. As described above, a secondary storage device 113 may contain a baseline image for a given software instantiation. Due to a growing image size resulting from software revisions, the memory manager module 101 may build diff files, or “delta” files, comprising data representative of the difference between the revised image and the baseline image. The delta file, which may be significantly smaller than the full size of the revised image, may be stored in the primary storage 115. Subsequently, a CPU 110 or other processing component requesting a page associated with the revised image may cause a page fault to be generated when the memory manager module 101 determines that the requested page does not exist in the primary storage 115. In response to the page fault, the memory manager module 101 may retrieve the baseline image of the requested page from the secondary storage and the diff data from the delta file in the primary storage 115. Using the baseline image file and the delta file, the memory manager module 101 may generate the requested page associated with the revised image, store the generated requested page in a swap pool location within the primary storage 115, and satisfy the CPU 110 request from the swap pool location. Similarly, the memory manage module 101 may satisfy a request for a cache line, as opposed to a page. The requested cache line as generated from the secondary storage 113 baseline instantiation and the primary storage delta file may be place in the cache 114 (instead of a swap pool in primary storage 115) for quick access and use by the CPU 110.

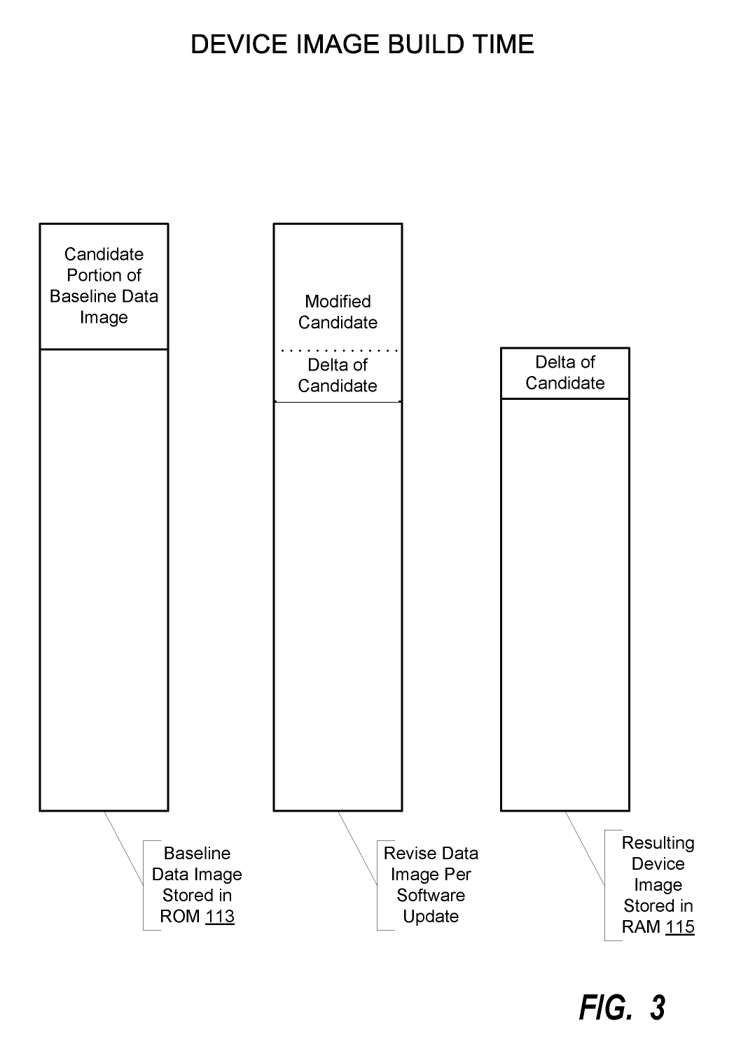

FIG. 3 illustrates generation of a device image at build time according to embodiments of the solution for ROM-based paging. The baseline image which includes the candidate portion is the original instantiation of a software stored in secondary storage such as ROM. The candidate portion of the baseline image is the portion of the software subject to modification via updates or software revisions and application of a ROM-based paging solution. The modified candidate is associated with a revised image and includes various differences from the baseline instantiation of the candidate portion (depicted as delta of candidate). As described above, the memory manager module 101 may generate a diff file based on the binary differences between the modified candidate of the revised image and the baseline candidate of the baseline image. The diff file, or delta of candidate, may be stored in primary storage.

Advantageously, and as can be inferred from the FIG. 3 illustration, by storing the delta of the candidate in the primary storage, as opposed to the full version of the modified candidate, primary storage capacity usage may be saved. That is, the resulting device image stored in the primary storage may be relatively smaller when generated according to embodiments of the solution, thus saving primary storage capacity for other purposes.

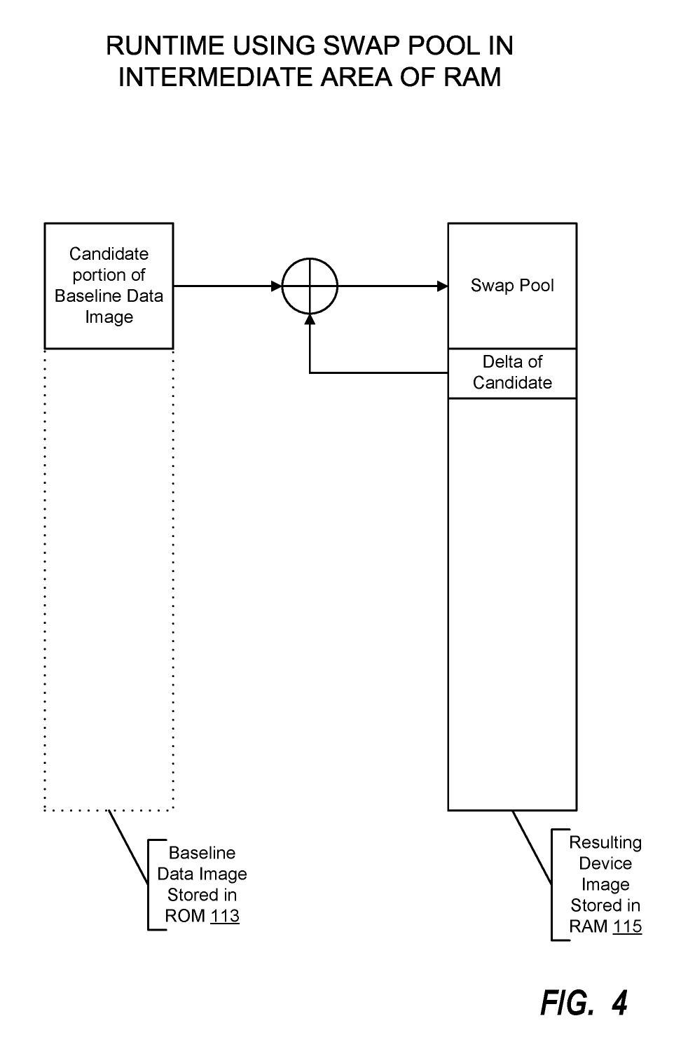

FIG. 4 illustrates a runtime execution according to embodiments of the solution for ROM-based paging using a swap pool in RAM. As previously described, the memory manager module 101 may build a diff file (“delta of candidate”) by comparing a baseline instantiation of a candidate portion of a software image stored in secondary storage with a modified candidate associated with a revised image of the software. The delta of the candidate is stored in the primary storage 115 and used by the memory manager 101 when a page fault occurs. To satisfy the page request that caused the page fault, the memory manager 101 retrieves the data block from the baseline instantiation and modifies it using the delta from the primary storage device to generate the requested page. The generated page is stored in a swap pool of the primary storage so that the page request may be satisfied from that location.

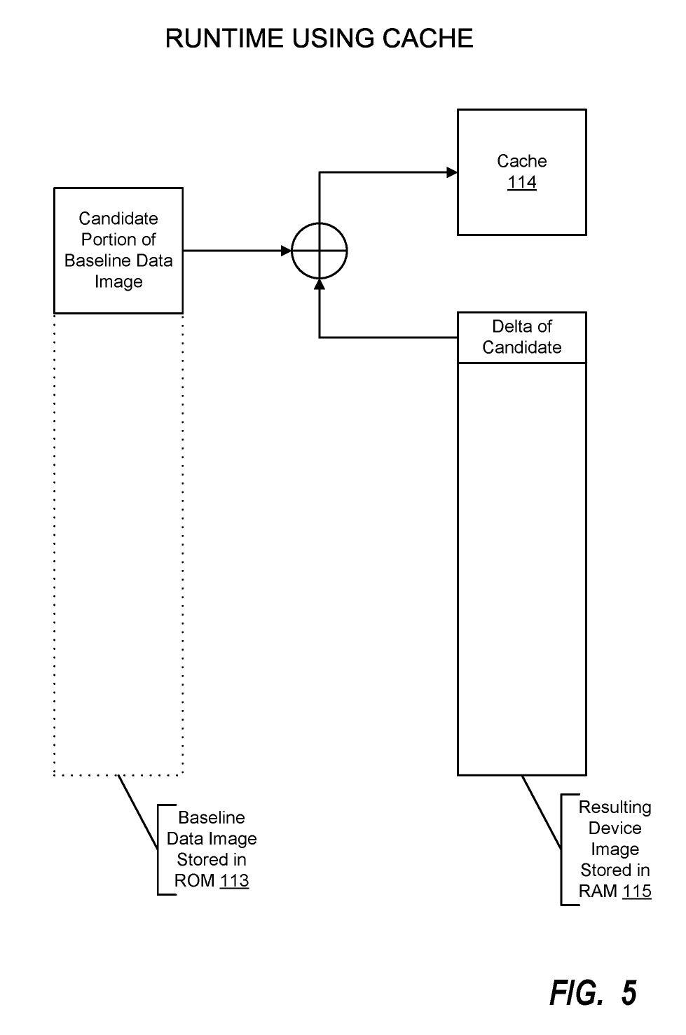

FIG. 5 illustrates a runtime execution according to embodiments of the solution for ROM-based paging using a cache. As previously described, the memory manager module 101 may build a diff file (“delta of candidate”) by comparing a baseline instantiation of a candidate portion of a software image stored in secondary storage with a modified candidate associated with a revised image of the software. In the FIG. 5 embodiment, the delta of the candidate is generated at a cache line granularity and stored in the primary storage 115 and used by the memory manager 101 when a cache line fault occurs. To satisfy the page request that caused the cache line fault, the memory manager 101 retrieves the data block from the baseline instantiation and modifies it using the delta from the primary storage device to generate and fill the requested cache line. The generated cache line is stored in a cache associated with the requesting processing component so that the data request may be satisfied from that location. Advantageously, in the FIG. 5 embodiment, a swap pool in the primary storage device is not required.

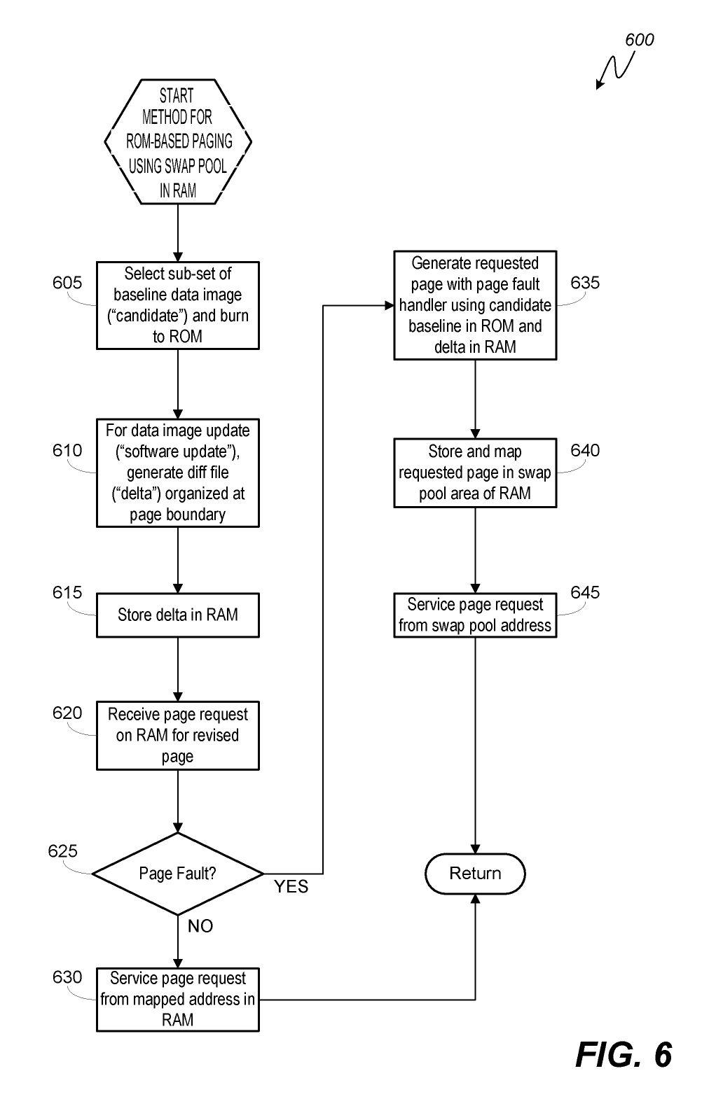

FIG. 6 is a logical flowchart of a method 600 for ROM-based paging according to embodiments of the solution using a swap pool in RAM. Beginning at block 605, a subset of a baseline image (i.e., a candidate) may be selected. The candidate (as part of the entire baseline image) may be burned to a secondary storage device, such as a ROM. At block 610, an update (e.g., software revision) to the candidate portion of the baseline image may trigger the generation of a diff file representing binary differences between the baseline candidate and the revised candidate. At block 615, the diff file (or delta) is stored in primary storage, such as DDR DRAM.

At block 620, a request for a page associated with the revised image may be received from a processing component, such as a CPU core. At decision block 625, if the requested page is stored in the primary storage, then the “NO” path is followed to block 630 and the page request is filled from the primary storage location. If, however, the requested page is not in primary storage, the “YES” path is followed to block 635.

At block 635, the requested page may be generated by retrieving the page from the baseline image in the secondary storage device and modifying it according to data stored in the diff file located in the primary storage device. At block 640, the newly generated requested page is stored in a swap pool area of the primary storage device. At block 645, the page request from the processing component is satisfied from the swap pool storage location. The method 600 returns.

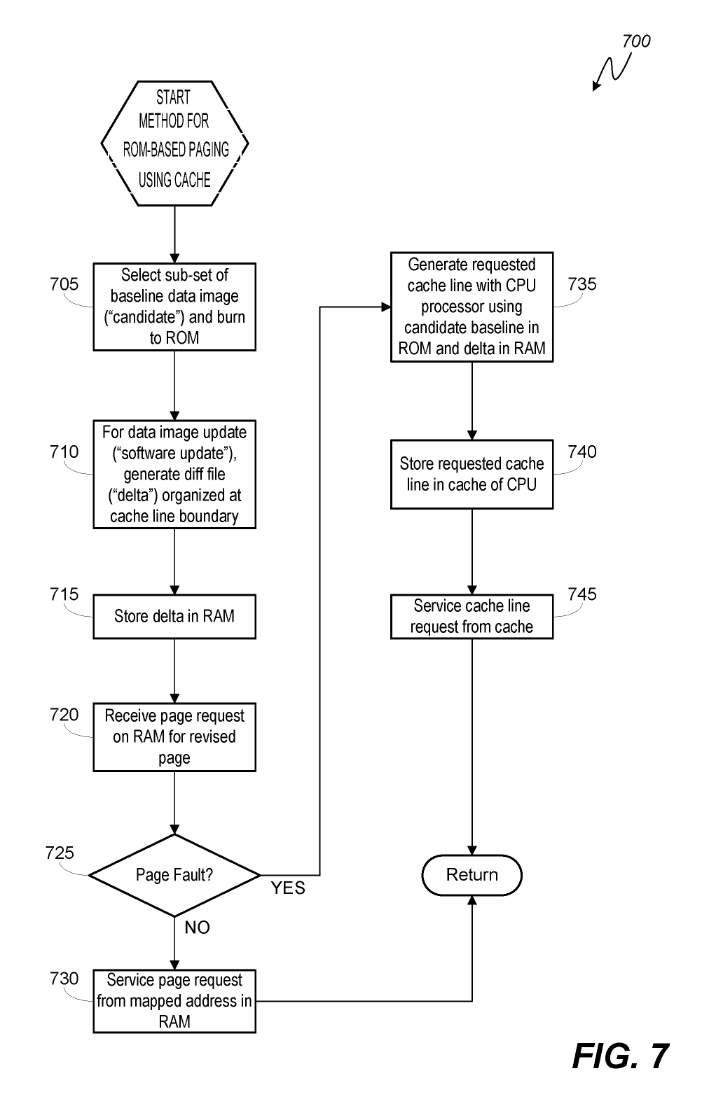

FIG. 7 is a logical flowchart of a method 700 for ROM-based paging according to embodiments of the solution using a cache. Beginning at block 705, a subset of a baseline image (i.e., a candidate) may be selected. The candidate (as part of the entire baseline image) may be burned to a secondary storage device, such as a ROM. At block 710, an update (e.g., software revision) to the candidate portion of the baseline image may trigger the generation of a diff file representing binary differences between the baseline candidate and the revised candidate. At block 715, the diff file (or delta) is stored in primary storage, such as DDR DRAM.

At block 720, a request for a page associated with the revised image may be received from a processing component, such as a CPU core. At decision block 725, if the requested page is stored in the primary storage, then the “NO” path is followed to block 730 and the page request is filled from the primary storage location. If, however, the requested page is not in primary storage, the “YES” path is followed to block 735.

At block 735, the requested page may be generated on a cache line level by retrieving the page from the baseline image in the secondary storage device and modifying it according to data stored in the diff file located in the primary storage device. At block 740, the newly generated requested page is stored in a cache associated with the processing component. At block 745, the page request from the processing component is satisfied on a cache line level from the cache. The method 700 returns.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example. Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the drawings, which may illustrate various process flows.

In one or more exemplary aspects, the functions described may be implemented in hardware, software, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer.

Therefore, although selected aspects have been illustrated and described in detail, it will be understood that various substitutions and alterations may be made therein without departing from the spirit and scope of the present invention, as defined by the following claims.

What is claimed is:

1. A method for memory paging in a system on a chip (“SoC”), the method comprising:
identifying a subset of a baseline data image stored in a secondary storage device;
determining that a revision data image requires an update of the subset;
generating a diff file and storing the diff file in a primary storage device, wherein the diff file represents binary differences between the revision data image subset and the baseline data image subset;
receiving a request for a data block associated with the revision data image, wherein the request causes a page fault;
generating the data block based on a combination of the baseline data image and the diff file; and
responding to the request by providing the generated data block.

2. The method of claim 1, wherein the generated data block is stored in a swap pool located in the primary storage device.

3. The method of claim 2, wherein the generated data block is a page in length.

4. The method of claim 1, wherein the generated data block is stored in a cache associated with a processing component that issued the request.

5. The method of claim 4, wherein the generated data block is a cache line in length.

6. The method of claim 1, wherein the secondary storage device is a read only memory (ROM) device.

7. The method of claim 1, wherein the primary storage device is a dynamic random access memory (DRAM) device.

8. The method of claim 7, wherein the DRAM device is a double data rate (DDR) memory device.

9. A computer system for memory paging in a system on a chip (“SoC”), the system comprising:
a memory manager module operable for:
identifying a subset of a baseline data image stored in a secondary storage device;
determining that a revision data image requires an update of the subset;
generating a diff file and storing the diff file in a primary storage device, wherein the diff file represents binary differences between the revision data image subset and the baseline data image subset;
receiving a request for a data block associated with the revision data image, wherein the request causes a page fault;
generating the data block based on a combination of the baseline data image and the diff file; and
responding to the request by providing the generated data block.

10. The system of claim 9, wherein the generated data block is stored in a swap pool located in the primary storage device.

11. The system of claim 10, wherein the generated data block is a page in length.

12. The system of claim 9, wherein the generated data block is stored in a cache associated with a processing component that issued the request.

13. The system of claim 12, wherein the generated data block is a cache line in length.

14. The system of claim 9, wherein the secondary storage device is a read only memory (ROM) device.

15. The system of claim 9, wherein the primary storage device is a dynamic random access memory (DRAM) device.

16. The system of claim 15, wherein the DRAM device is a double data rate (DDR) memory device.

17. A computer system for memory paging in a system on a chip (“SoC”), the system comprising:
means for identifying a subset of a baseline data image stored in a secondary storage device;
means for determining that a revision data image requires an update of the subset;
means for generating a diff file and storing the diff file in a primary storage device, wherein the diff file represents binary differences between the revision data image subset and the baseline data image subset;
means for receiving a request for a data block associated with the revision data image, wherein the request causes a page fault;
means for generating the data block based on a combination of the baseline data image and the diff file; and
means for responding to the request by providing the generated data block.

18. The computer system of claim 17, wherein the generated data block is stored in a swap pool located in the primary storage device.

19. The computer system of claim 18, wherein the generated data block is a page in length.

20. The computer system of claim 17, wherein the generated data block is stored in a cache associated with a processing component that issued the request.

21. The computer system of claim 20, wherein the generated data block is a cache line in length.

22. The computer system of claim 17, wherein the secondary storage device is a read only memory (ROM) device.

23. The computer system of claim 22, wherein the primary storage device is a dynamic random access memory (DRAM) device.

24. A computer program product comprising a computer usable device having a computer readable program code embodied therein, said computer readable program code adapted to be executed to implement a method for memory paging in a system on a chip (“SoC”), said method comprising:
identifying a subset of a baseline data image stored in a secondary storage device;
determining that a revision data image requires an update of the subset;
generating a diff file and storing the diff file in a primary storage device, wherein the diff file represents binary differences between the revision data image subset and the baseline data image subset;
receiving a request for a data block associated with the revision data image, wherein the request causes a page fault;
generating the data block based on a combination of the baseline data image and the diff file; and
responding to the request by providing the generated data block.

25. The computer program product of claim 24, wherein the generated data block is stored in a swap pool located in the primary storage device.

26. The computer program product of claim 25, wherein the generated data block is a page in length.

27. The computer program product of claim 24, wherein the generated data block is stored in a cache associated with a processing component that issued the request.

28. The computer program product of claim 27, wherein the generated data block is a cache line in length.

29. The computer program product of claim 24, wherein the secondary storage device is a read only memory (ROM) device.

30. The computer program product of claim 24, wherein the primary storage device is a dynamic random access memory (DRAM) device.
